(19) United States
(12) Patent Application Publication
(10) Pub. No.: US 2012/0138456 A1
(43) Pub. Date: Jun. 7, 2012

(54) SOLAR FUELS GENERATOR

(75) Inventors: Joshua M. Spurgeon, Pasadena, CA (US); Nathan S. Lewis, La Canada, CA (US)

(73) Assignee: THE CALIFORNIA INSTITUTE OF TECHNOLOGY, Pasadena, CA (US)

(21) Appl. No.: 13/312,567

(22) Filed: Dec. 6, 2011

Related U.S. Application Data
(60) Provisional application No. 61/420,032, filed on Dec. 6, 2010.

(51) Int. Cl. C25B 9/00; H01L 31/18; H01L 31/04

(52) U.S. Cl. 204/252; 438/57; 257/E31.11

(57) ABSTRACT

The solar fuels generator includes photoanodes that each extends outward from a first side of a membrane. The generator also includes photocathodes that each extends outward from a second side of the membrane. The photocathodes each includes a p-type semiconductor and the photoanodes each includes an n-type semiconductor. The p-type semiconductors are in electrical communication with the n-type semiconductors.

### CROSS REFERENCE TO RELATED APPLICATIONS

This Application claims the benefit of U.S. Provisional Patent Application Ser. No. 61/420,032, filed on Dec. 6, 2010, and incorporated herein in its entirety.

### STATEMENT REGARDING FEDERALLY SPONSORED RESEARCH

This invention was made with government support under DE-FG02-07ER46405 awarded by the Department of Energy. The government has certain rights in the invention.

### FIELD OF THE INVENTION

The present invention relates to solar generators, and more particularly, to solar fuel generators.

### BACKGROUND

Solar cells are used to generate electrical energy from sunlight. While these cells can generate electricity from sunlight, they do not efficiently store the generated energy. As a result, the energy must be used immediately or stored in devices such as batteries. Storing large amounts of energy in batteries is impractical and expensive. An alternative to storing solar energy in a device is to convert the solar energy into a fuel that can be used at a later time. A solar fuel generator is a device that converts the energy from the sun and water into a fuel such as hydrogen fuel. As a result, there is a need for a practical solar fuel generator.

### SUMMARY

The solar fuels generator includes photoanodes that each extends outward from a first side of a membrane. The generator also includes photocathodes that each extends outward from a second side of the membrane. The photocathodes each includes a p-type semiconductor and the photoanodes each includes an n-type semiconductor. The p-type semiconductors are in electrical communication with the n-type semiconductors.

In one example of the solar fuels generator, the membrane includes an intermediate layer between an anode layer and a cathode layer. The n-type semiconductors each extend into the anode layer and the p-type semiconductors each extends into the cathode layer. The intermediate layer provides the electrical communication between the p-type semiconductors and the n-type semiconductors.

A method of forming the solar fuels generator is also disclosed. The method includes generating an anode precursor that includes photoanodes extending outward from an anode layer. The method also includes generating a cathode precursor that includes photocathodes extending outward from a cathode layer. The photoanodes each includes an n-type semiconductor and the photocathodes each includes a p-type semiconductor. The method further includes bonding the anode layer to the cathode layer with an intermediate layer that provides electrical communication between the n-type semiconductors and the p-type semiconductors.

### BRIEF DESCRIPTION OF THE FIGURES

FIG. 1A is a perspective view of a solar fuel generator.

FIG. 1B is a cross section of the solar fuel generator shown in FIG. 1A.

FIG. 2A through FIG. 2H illustrate a method of forming a solar fuels generator.

### DESCRIPTION

As used herein and in the appended claims, the singular forms “a,” “and,” and “the” include plural referents unless the context clearly dictates otherwise. Thus, for example, reference to “a membrane” includes a plurality of such membranes and reference to “the semiconductor” includes reference to one or more semiconductors known to those skilled in the art, and so forth.

Also, the use of “or” means “and/or” unless stated otherwise. Similarly, “comprise,” “comprises,” “comprising” “include,” “includes,” and “including” are interchangeable and not intended to be limiting.

It is to be further understood that where descriptions of various embodiments use the term “comprising,” those skilled in the art would understand that in some specific instances, an embodiment can be alternatively described using language “consisting essentially of” or “consisting of.”

Unless defined otherwise, all technical and scientific terms used herein have the same meaning as commonly understood to one of ordinary skill in the art to which this disclosure belongs. Although methods and materials similar or equivalent to those described herein can be used in the practice of the disclosed methods and compositions, the exemplary methods, devices and materials are described herein.

The publications discussed above and throughout the text are provided solely for their disclosure prior to the filing date of the present application. Nothing herein is to be construed as an admission that the inventors are not entitled to antedate such disclosure by virtue of prior disclosure.

A solar fuels generator has wires of an n-type semiconductor extending outward from a side of a membrane and wires of a p-type semiconductor extending outward from the opposite side of the membrane. During operation of the solar fuels generators, light is incident on the semiconductors on one side of the membrane and those semiconductors absorb a portion of the light. The remainder of the light passes through the membrane and is absorbed by the semiconductors on the other side of the membrane. As a result, the membrane must be sufficiently transparent to the incoming light that the incoming light can interact with the semiconductors on both sides of the membrane. Additionally, during operation of the solar fuels generator, the membrane conducts cations and/or anions produced by redox reactions that occur at the semiconductors while being substantially impermeable to hydrogen and oxygen. Additionally, the membrane provides electrical communication between the n-type semiconductors and the p-type semiconductors. As a result, the membrane must perform multiple functions during the operation of the solar fuel generator.

The requirements for the membrane have surprisingly been achieved with a multi-layer membrane that includes an intermediate layer between an anode layer and a cathode layer. The n-type semiconductors extend outward from the anode layer and are also in electrical communication with the intermediate layer. The p-type semiconductors extend outward from the cathode layer and are also in electrical communication with the intermediate layer. The intermediate layer provides the electrical communication between the n-type semiconductors and the p-type semiconductors. With this configuration, the inventors have been able to generate a membrane that allows the wires to absorb more than 65% of the incident light in a range of 500-700 nm even when the incident light is substantially perpendicular to the membrane, has a hydrogen cationic conductivity greater than 50 mS/cm, and is substantially impermeable to H₂ and O₂ in that hydrogen crossover is less than 0.02 Ma/cm². Accordingly, the inventors have generated multifunctional membranes suitable for use in a solar fuel generator.

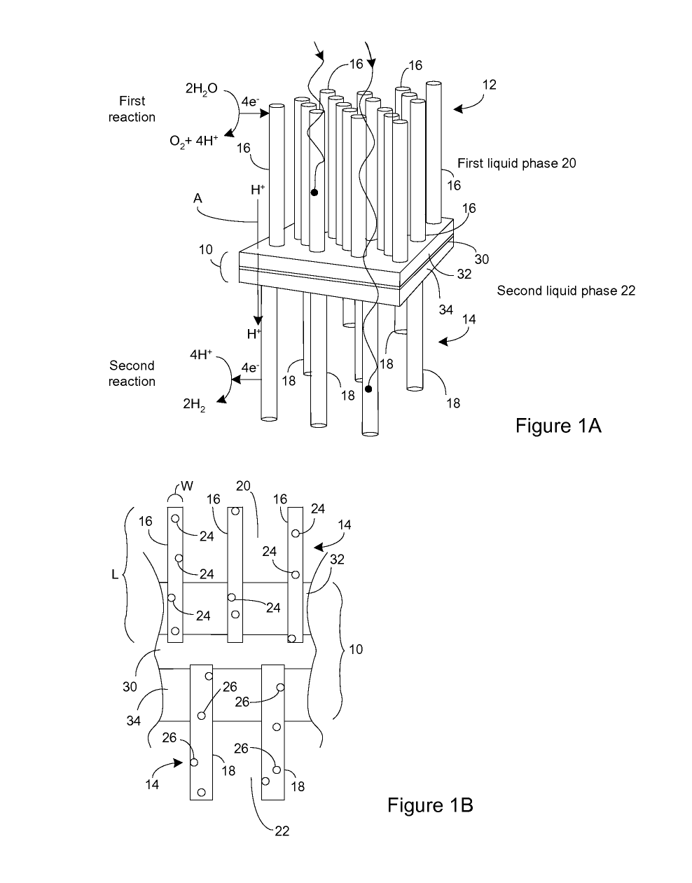

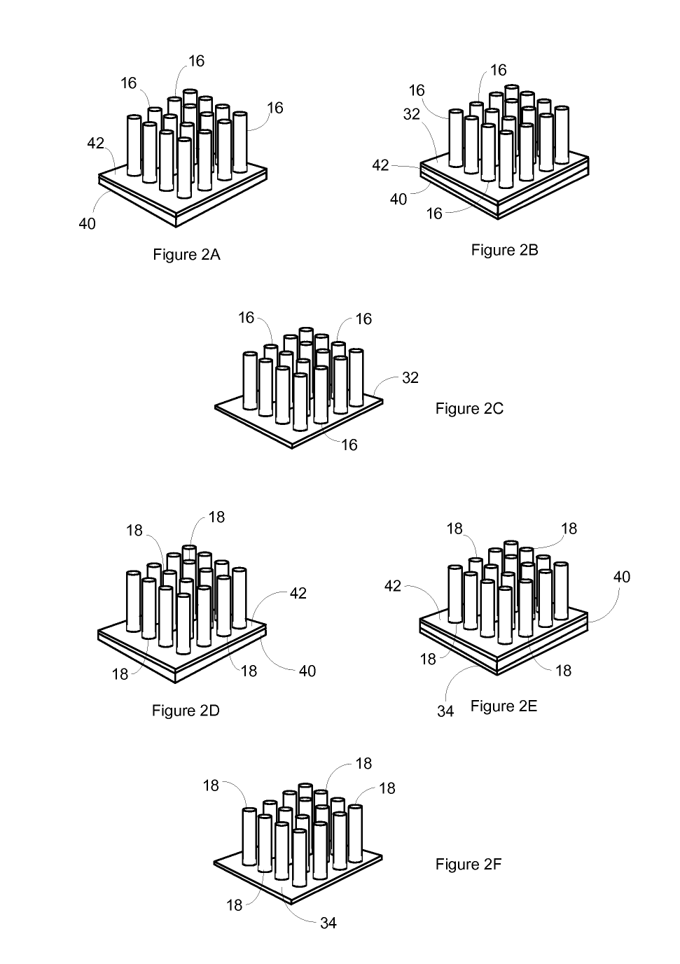

FIG. 1A is a perspective view of a solar fuel generator. FIG. 1B is a cross section of the solar fuel generator shown in FIG. 1A. The solar fuel generator includes a membrane 10 that supports photoanodes 12 and photocathodes 14. Photoanodes and photocathodes are examples of photoelectrodes that convert incident light into electrical energy. The photoanodes 12 include an anode semiconductor 16 selected to absorb light at a wavelength to which the anodes will be exposed during operation. Additionally, the photocathodes include a cathode semiconductor 18 selected to absorb light at a wavelength to which the photocathodes 14 will be exposed during operation. The anode semiconductor 16 is an n-type semiconductor while the cathode semiconductor 18 is a p-type semiconductor. Additionally, the bandgap of the photoanode 12 semiconductors is larger than the bandgap of the photocathode semiconductors 18. Suitable anode semiconductors 16 include, but are not limited to, metal oxides, oxynitrides, sulfides, and phosphides that are stable in an oxidizing environment such as WO₃, TiO₂, and TaON. Suitable cathode semiconductors 18 include, but are not limited to, p-type silicon, InP, Cu₂O, GaP, and Wse₂.

The membrane 10 separates a first liquid phase 20 from a second liquid phase 22. For instance, although not shown, the perimeter of the membrane 10 can be clamped between flanges that from the side of a cell into the interior of a cell. When the perimeter of the membrane 10 is clamped in the flanges, the membrane 10 spans the interior of the cell. The first liquid phase 20 can be located in the cell on one side of the membrane 10 with the photoanodes 12 immersed in the first liquid phase 20 and the second liquid phase 22 can be located in the cell on the opposing side of the membrane 10 with the photocathodes 14 immersed in the second liquid phase 22. In some instances, the first liquid phase 20 and the second liquid phase 22 each includes water.

During operation, the solar fuels generator is exposed to light such as sunlight. In some instances, the solar fuels generator is oriented such that the light travels through the photoanodes before reaching the photocathodes 14. Since the anode semiconductor 16 has a larger bandgap than the cathode semiconductor 18, the photoanodes 12 absorb higher energy (shorter wavelength) light and allow lower energy (longer wavelength) light to pass through the membrane 10 to the photocathodes 14. The photocathodes 14 can then absorb the longer wavelengths.

The absorption of light by an anode semiconductor 16 generates hole-electron pairs within the anode semiconductor 16. The immersion of the n-type anode semiconductor 16 in the first liquid phase 20 produces an electrical field that causes the holes to move to the surface of the anode semiconductor 16 and out into the first liquid phase 20 where water in the first liquid phase 20 is oxidized. The oxidation of water is labeled reaction 1 in FIG. 1A. Oxidation of the water produces gaseous oxygen and electrons that move into the anode semiconductor 16. The resulting buildup of electrons in the anode semiconductor 16 in the presence of the electrical field causes movement of electrons into the cathode semiconductor 18.

The oxidation of the water in the first liquid phase 20 also generates hydrogen cations (H⁺, called protons below) in the first liquid phase 20. In some instances, the membrane 10 is cationically conductive. As a result, the protons can travel through the membrane 10 and enter the second liquid phase 22 in response to the Ph gradient resulting from the generation of protons in the first liquid phase 20. The movement of the protons from the first liquid phase 20 into the second liquid phase 22 is shown by the arrow labeled A in FIG. 1A.

The absorption of light by the cathode semiconductor 18 generates hole-electron pairs within the cathode semiconductor 18. The immersion of the p-type cathode semiconductor 18 in the second liquid phase 22 produces an electrical field that causes the electrons within the cathode semiconductor 18 to move to the surface of the cathode semiconductor 18 where they are given to the protons to form hydrogen gas. The reduction of the protons is labeled reaction 2 in FIG. 1A. The resulting hydrogen gas can be stored for use as hydrogen fuel.

In some instances, the photoanodes 12 include one or more anode catalysts 24 that catalyze the first reaction. For instance, the anode catalyst can catalyze water oxidation. The one or more anode catalysts 24 can be positioned on the anode semiconductor 16. In some instances, the one or more catalysts directly contact the anode semiconductor 16. In some instances, the one or more anode catalysts 24 coat the anode semiconductor 16 or are positioned in islands on the anode semiconductor 16 as shown in FIG. 1B. Suitable anode catalysts 24 include, but are not limited to, IrO₂, RuO₂, CO₃O₄, MnO₂, and NiFeOₓ.

In some instances, the photocathodes 14 include one or more cathode catalysts 26 that catalyze the first reaction. For instance, the cathode catalyst can catalyze proton reduction. The one or more cathode catalysts 26 can be positioned on the cathode semiconductor 18. In some instances, the one or more catalysts directly contact the cathode semiconductor 18. In some instances, the one or more cathode catalysts 26 coat the cathode semiconductor 18 or are positioned in islands on the cathode semiconductor 18 as shown in FIG. 1B. Suitable cathode catalysts 26 include, but are not limited to, Pt, NiMo, and NiCo.

The cathode semiconductor 18 and the anode semiconductor 16 are high aspect ratio structures. The aspect ratio is the ratio of the length of the semiconductor (labeled L in FIG. 1B): width of the semiconductor (labeled w in FIG. 1B). Narrowing the width of the semiconductors reduces the distance that minority carriers must diffuse radially in order to reach the surface of the semiconductor. Accordingly, a suitable average width for the cathode semiconductors 18 and/or the anode semiconductors 16 include can be about the minority-carrier diffusion length of the material. In some instances, the average width for the cathode semiconductors 18 and/or the anode semiconductors 16 is in a range of 100 nm-10 μm.

Since the semiconductors extend into the membrane 10, the membrane 10 supports the semiconductors so the far end of each semiconductor is held above the membrane 10. Accordingly, increasing the portion of the semiconductor embedded in the membrane 10 can increase the support of the semiconductors. However, it is possible that increasing the portion of the semiconductor in the membrane 10 can increase the portion of light that is absorbed by the membrane 10 rather than by the semiconductor. A suitable average percentage of the semiconductor length that is inside of the membrane 10 includes percentages greater than 10%, or 20% and/or less than 80%, or 100%. In some instances, the cathode semiconductors 18 do not extend outside of the membrane and/or the anode semiconductors 16 do not extend outside of the membrane.

High aspect ratio structures reduce the charge-carrier flux to the surface of the semiconductor. This reduced flux can reduce the turnover frequency required of any catalysts and can permit the use of more abundant and less active catalysts. Suitable average aspect ratios for the cathode semiconductors 18 include, but are not limited to, ratios greater than 2:1, or 5:1, and/or less than 50:1, 100:1, or 200:1. Additionally or alternately, suitable average aspect ratios for the anode semiconductors 16 include, but are not limited to, ratios greater than 2:1, or 5:1, and/or less than 50:1, 100:1, or 200:1. In one example, the average aspect ratio for the cathode semiconductors 18 and/or the anode semiconductors 16 is in a range of 44:1-70:1. The anode semiconductors 16 can have the same average dimensions as the cathode semiconductors 18 or different average dimensions from the anode semiconductors 16. Wire shaped anode semiconductors 16 and/or the cathode semiconductors 18 can support the above aspect ratios.

The spaces between the cathode semiconductors and the spaces between the anode semiconductors 16 provide the pathway for the protons to travel to and/or from the membrane 10. In order to provide pathways between the anode semiconductors 16, the location where the semiconductors contact the membrane 10 can be substantially regularly spaced on the membrane 10. For instance, the semiconductors can be periodically positioned on the membrane 10 in a grid, array, or other patterns. A suitable average separation between each anode semiconductor 16 and the nearest anode semiconductor 16 includes, but is not limited to, separations greater than 100 nm and/or less than 20 μm. A suitable average separation between each cathode semiconductor 18 and the nearest cathode semiconductor 18 includes, but is not limited to, separations greater than 100 nm and/or less than 20 μm. In one example, the anode semiconductors 16 are arranged in a square grid arrangement and the average separation between each anode semiconductor 16 and the nearest cathode semiconductor 18 is about 7.0 μm and/or the cathode semiconductors 18 are arranged in a square grid arrangement and the average separation between each cathode semiconductors 18 and the nearest cathode semiconductor 18 is about 7.0 μm.

The arrangement of the anode semiconductors 16 on the membrane at the location where the semiconductors contact the membrane 10 can be the same as the arrangement of the cathode semiconductors 18 on the membrane 10 both in terms of spacing between semiconductors and the pattern in which the semiconductors are arranged on the membrane 10. In these instances, all or a portion of the anode semiconductors 16 can each optionally be aligned with a cathode semiconductor 18 on the opposing side of the membrane 10. Alternately, the arrangement of the anode semiconductors 16 on the membrane 10 at the location where the anode semiconductors 16 contact the membrane 10 can be different from the arrangement of the cathode semiconductors 18 on the membrane 10 in terms of spacing between semiconductors and/or the pattern in which the semiconductors are arranged on the membrane 10. In these instances, at least a portion of the anode semiconductors 16 are not aligned with a cathode semiconductor 18 on the opposing side of the membrane 10. FIG. 1A shows the anode semiconductors 16 arranged in the same pattern as the cathode semiconductors 18 but in a different spatial arrangement. As a result, at least a portion of the anode semiconductors 16 are not aligned with a cathode semiconductor 18 on the opposing side of the membrane 10.

Although FIG. 1A and FIG. 1B show the semiconductors as being substantially parallel to one another along their length, the semiconductors need not be parallel. For instance, the semiconductors can be sufficiently flexible that they curve or bend due to the action of gravity or and/or other forces and/or can be curved or bent as a result of the fabrication process. Curving of the semiconductors can reduce the number of open paths from above the semiconductors down to the membrane 10. Reducing the number of these pathways can increase interaction between the incoming light and the semiconductors. Increasing this interaction can increase the fraction of incident light absorbed by the semiconductors.

The above description of the solar fuels generator operation shows that the membrane 10 provides a variety of different functions to the solar fuels generator. For instance, the membrane 10 must: conduct ions produced by the redox reactions at the photoanode 12; must separate the gaseous hydrogen and oxygen products to prevent them from re-combining to form water; provide electrical communication between the photoanodes 12 and photocathodes 14; and be sufficiently transparent to the incoming light that the light can be absorbed by both the anode semiconductors 16 and the cathode semiconductors 18; and provide enough structural support to the anode semiconductors 16 and the cathode semiconductors 18 that these structures are sufficiently vertical for pathways for the protons to travel to and/or from the membrane 10. These properties can be achieved using a multi-layer membrane as shown in FIG. 1A and FIG. 1B.

First 1A shows the membrane 10 having an intermediate layer 30 between an anode layer 32 and a cathode layer 34. The anode layer 32 and the cathode layer 34 can be immobilized relative to the intermediate layer 30. The photoanodes 12 extend through the anode layer 32 and are in direct physical contact with the intermediate layer 30. The photocathodes 14 extend through the cathode layer 34 and are in direct physical contact with the intermediate layer 30. The intermediate layer 30 is electrically conducting and accordingly provides an electrical connection between the photoanodes 12 and the photocathodes 14. This connection connects in series two different semiconductors that have energy levels appropriate for generating the photovoltage necessary to generate fuel (i.e., to split water into H₂ and O₂).

Although the photoanodes 12 and photocathodes 14 are shown extending part way into the intermediate layer 30, the photoanodes 12 and photocathodes 14 need not extend into the intermediate layer 30. For instance, the end of the photoanodes 12 can be substantially flush with a surface of the intermediate layer 30 and/or the end of the photocathodes 14 can be substantially flush with a surface of the intermediate layer 30. Alternately, the photoanodes 12 can terminate within the anode layer 32 and the intermediate layer 30 can extend into the anode layer 32 to contact the photoanodes 12 and/or the photocathodes 14 can terminate within the cathode layer 34 and the intermediate layer 30 can extend into the cathode layer 34 to contact the photocathodes 14.

The material of the anode layer 32 can be the same or different from the material of the cathode layer 34. A suitable material for the anode layer 32 and the cathode layer 34 includes, but is not limited to, ionomers and mixtures of ionomers. Ionomers are polymers that include electrically neutral repeating units and ionized repeating units. Suitable ionomers include copolymers of a substituted or unsubstituted alkylene and an acid such as sulfonic acid. In one example, the ionomer is a copolymer of tetrafluoroethylene and perfluoro-3,6-dioxa-4-methyl-7-octene-sulfonic acid. An example is represented by the following Formula I:

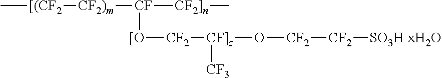

wherein m, n, and z are each greater than 0, or each greater than 1. A suitable material having a structure according to Formula I is sold under the trademark NAFION®. The ionomer represented by Formula I is substantially electrically non-conducting. As a result, in some instances, the anode layer 32 and/or the cathode layer 34 is substantially electrically non-conducting. In some instances, the anode layer 32 and/or the cathode layer 34 are electrically conducting.

The intermediate layer 30 needs to be electrically conducting in order to provide electrical communication between the anode semiconductors 16 and the cathode semiconductors 28. Additionally, the intermediate layer 30 needs to be at least marginally ionically conducting in order to permit ions to travel from the first liquid phase 20 to the second liquid phase 22. An intermediate layers with a lower ionic conductivity can be used by reducing the thickness of the intermediate layer.

A suitable material for the intermediate layer 30 includes, but is not limited to, ionomers and mixtures of ionomers. Suitable ionomers for inclusion in the intermediate layer 30 include, but are not limited to, ionomers that include sulfonyl groups where a portion of the sulfonyl groups are deprotonated and carry a negative charge while another portion of the sulfonyl groups remain uncharged. An example of an ionomer including charged sulfonyl groups is poly(styrene sulfonate). Another suitable ionomer for inclusion in the intermediate layer 30 includes thiophene groups where a portion of the thiophene groups carry a positive charge while another portion of the thiophene groups are uncharged. An example of an ionomer including charged thiophene groups is poly(3,4-ethylenedioxythiophene). An example of a suitable mixture of the ionomers is poly(3,4-ethylenedioxythiophene): poly(styrene sulfonate) (PEDOT: PSS).

Many electrically conducting polymers and additives that are suitable for use as the intermediate layer 30 because they are electrically conducting absorb undesirably high levels of light and are accordingly undesirable for use as the anode layer 32 and/or the cathode layer 34. However, as noted above, the intermediate layer 30 must be electrically conducting in order to provide a serial connection that allows for the generation of the required photovoltages. As a result, many of the polymers that are suitable for use as the intermediate layer 30 absorb light. Accordingly, it can be desirable to reduce the thickness of the intermediate layer 30 in order to reduce the amount of light absorption that occurs and also to reduce any negative effect that the intermediate layer 30 has on the conduction of ions. A suitable average thickness for the intermediate layer 30 includes, but is not limited to, a thickness greater than 100 nm, or 200 nm, and/or less than 1 μm, or 2 μm.

The above discussion discloses use of the same material for both the anode layer 32 and the cathode layer 34; however, the anode layer 32 and cathode layer 34 can be constructed of different materials. For instance, the anode layer 32 can be a cationically conductive material while the cathode layer 34 is an anionically conductive material. In this instance, the second reaction illustrated in FIG. 1A can instead be written as 2H₂O+2e⁻→H₂(g)+2OH⁻. The hydrogen gas from this reaction is collected to serve as hydrogen fuel. Additionally, the hydroxide anion from this reaction travels through the anionically conductive material of the cathode layer 34 into the intermediate layer 30 where it combines with the protons to form water.

Suitable materials for an anionically conducting anode layer 32 include, but are not limited to, polymers that include sulfones in the backbone. An example of a suitable polymer having sulfones in the backbone is a poly(arylene ether sulfone) functionalized with quaternary ammonium groups. A suitable poly(arylene ether sulfone) functionalized with quaternary ammonium groups is represented by the following Formula II:

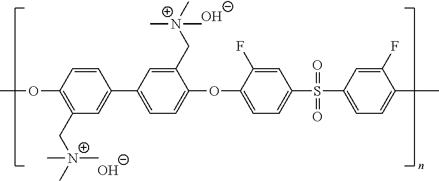

wherein n is greater than 1 or greater than 2.

As is evident from FIG. 1A and FIG. 1B, the anode layer 32 and/or the cathode layer 34 provide mechanical support to the anode semiconductors 16 and/or the cathode semiconductors 18. Increasing the thickness of the anode layer 32 and/or the cathode layer 34 increases the level of support provided to the semiconductors in the layer. Accordingly, in some instances, the anode layer 32 and/or the cathode layer 34 are each thicker than the intermediate layer 30. As suitable average thickness for the anode layer 32 and/or the cathode layer 34 includes, but is not limited to, a thickness greater than 1 μm, 10 μm, or 20 μm and/or less than 60 μm, 100 μm, or 500 μm. In one example, the anode layer 32 and the cathode layer 34 each have an average thickness in a range of 50 μm to 70 μm and are both thicker than the intermediate layer 30. In another example, the anode layer 32 has an average thickness in a range of 50 μm to 70 μm and the cathode layer 34 has a thickness of about 40 μm and both the anode layer 32 and the cathode layer 34 are thicker than the intermediate layer 30. A suitable ratio for the thickness of the anode layer 32:intermediate layer 30 and/or the thickness of the anode layer 32:intermediate layer 30 includes, but is not limited to, ratios greater than 5:1, or 10:1, or 50:1.

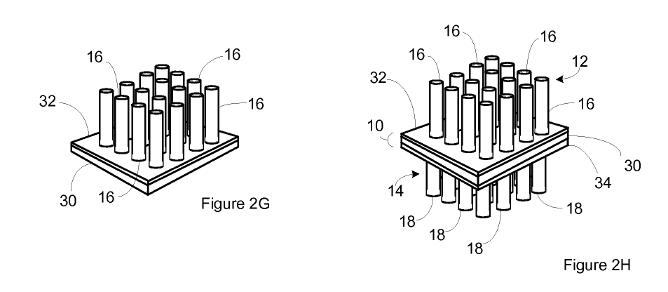

A suitable method for forming a solar fuels generator according to FIG. 1A and FIG. 1B is illustrated in FIG. 2A through FIG. 2H. A substrate 40 that includes or consists of the anode semiconductor material is covered with a mask 42. The mask 42 is patterned such that the locations where the anode semiconductors 16 are desired are exposed while the mask 42 protects the remainder of the substrate 40. A suitable mask 42 includes, but is not limited to, a SiO₂ mask 42. The mask 42 can be patterned using technologies such as photolithography. The anode semiconductor 16 are grown on the exposed regions of the substrate 40 so as to provide an array of anode semiconductors 16 on the substrate 40 as shown in FIG. 2A. The anode semiconductors 18 can be grown on the substrate 40 using methods such as epitaxial growth via chemical vapor deposition or emplate growth by electrodeposition. If it is desirable for the anode semiconductor 16 to be doped with dopant such as an n-type dopant, the anode semiconductor 16 can be doped after the growth of the anode semiconductor 16 on the substrate 40.

If an anode catalyst is to be included on the anode semiconductors, the anode catalyst can be added to the semiconductor using methods such as electrodeposition, electroless deposition, thermal evaporation, sputtering, atomic layer deposition, casting and sintering, and using molecular linkers.

The material for the anode layer 32 can be cast from solution onto the mask 42 on the device precursor of FIG. 2A so as to provide the device precursor of FIG. 2B. The substrate 40 and mask 42 are removed from the device precursor of FIG. 2B to provide the photoanode precursor of FIG. 2C. Suitable methods for removing the substrate 40 and mask 42 include, but are not limited to, mechanical scraping, sonication, and chemical dissolution of the substrate.

The portion of the method illustrated in FIG. 2A through FIG. 2C is repeated for the photocathode portion of the solar fuels generator. A substrate 40 that includes or consists of the cathode semiconductor material is covered with a mask 42. The mask 42 is patterned such that the locations where the cathode semiconductors 18 are desired are exposed while the mask 42 protects the remainder of the substrate 40. A suitable mask 42 includes, but is not limited to, an SiO₂ mask 42, and porous templates such anodic aluminum oxide. The cathode semiconductors 18 are grown on the exposed regions of the substrate 40 so as to provide an array of cathode semiconductors 18 on the substrate 40 as shown in FIG. 2D. The cathode semiconductors 18 can be grown on the substrate 40 using methods such as epitaxial growth via chemical vapor deposition or emplate growth by electrodeposition. If it is desirable for the cathode semiconductors 18 to be doped with dopant such as a p-type dopant, the cathode semiconductors 18 can be doped after the growth of the anode semiconductor 16 on the substrate 40.

If a cathode catalyst is to be included on the cathode semiconductor, the cathode catalyst can be added to the cathode semiconductors using methods such as electrodeposition, electroless deposition, thermal evaporation, sputtering, atomic layer deposition, casting and sintering, and using molecular linkers.

The material for the cathode layer 34 can be cast from solution onto the mask 42 on the device precursor of FIG. 2D so as to provide the device precursor of FIG. 2E. The substrate 40 and mask 42 are removed from the device precursor of FIG. 2E to provide the photocathode precursor of FIG. 2F. Suitable methods for removing the substrate 40 and mask 42 include, but are not limited to, scraping, sonication, and chemical dissolution of the substrate.

A liquid that include the material for the intermediate layer 30 is applied to the back side of the anode layer 32 and/or the cathode layer 34 to provide an anode precursor and/or a cathode precursor as shown in FIG. 2G. Before the liquid is dried, the anode precursor and cathode precursor are pressed together with the liquid contacting both the anode layer 32 and the cathode layer 34. The liquid is then dried so as to form an intermediate layer 30 adhered to both the anode precursor and the cathode precursor as shown in FIG. 2H.

Although the above method discloses placing the anode catalyst on the anode semiconductors before forming the anode layer, the anode catalyst can be placed on the anode semiconductors after forming the anode layer. For instance, when a portion of the anode semiconductors remains exposed after forming the anode layer, the anode catalyst can be formed on the exposed portion of the anode semiconductors. Although the above method discloses placing the cathode catalyst on the cathode semiconductors before forming the cathode layer, the cathode catalyst can be placed on the cathode semiconductors after forming the cathode layer. For instance, when a portion of the cathode semiconductors remains exposed after forming the cathode layer, the cathode catalyst can be formed on the exposed portion of the cathode semiconductors.

The following examples are intended to illustrate but not limit the disclosure. While they are typical of those that might be used, other procedures known to those skilled in the art may alternatively be used.

### EXAMPLES

### Example 1

A solar fuels generator according to FIG. 1 was generated in order to test the performance of the membrane. Because the goal was testing of the membrane performance rather than testing the performance of the solar fuels generator itself, the solar fuels generator used p-type silicon as a structure to represent both the anode semiconductors and the cathode semiconductors.

An SiO₂ mask was patterned on a silicon substrate and silicon wires were grown from a patterned Cu catalyst in a square arrangement with a 7.0 μm pitch. The silicon wires were 90±15 μm long, and ˜1.5-1.7 μm in diameter. The silicon wires were doped p-type. Solutions of NAFION® in N,N-dimethylformamide (DMF) were prepared by addition of 1.2 mL of DMF to 3.0 mL of perfluorosulfonic acid-polytetrafluoroethylene (PTFE) copolymer (NAFION®, 5% w/w in a water/alcohol mixture, Alfa Aesar), followed by heating at 140° C. to evaporate the water/alcohol mixture until the solution volume was reduced to ˜1.2 mL. This solution was spin-coated onto the wire arrays at 1000 rpm for 30 s, and the arrays were then heated at 140° C. for ˜20 min. This process was performed three times on each wire array, and produced a ˜50 μm thick NAFION® film at the base of the wires. The Si wire array and NAFION® layer (device precursor) were then mechanically removed from the underlying Si(111) substrate using a razor blade. Membrane areas were typically >3 cm², to fully cover glass flanges in a permeation cell that was used for characterization experiments.

Each of the device precursors was laid out on a different thin sheet of flexible plastic with the wires being between the sheet of plastic and the NAFION® layer. Ethanol was dripped onto the device precursors, causing the NAFION® layer to expand significantly. The result was then carefully flattened against the plastic substrate. The intermediate layer was the formed by spin casting 2-3 drops of a high conductivity dispersion of poly(3,4-ethylenedioxythiophene): poly(styrene sulfonate) (PEDOT: PSS), 2.2-2.6% in H₂O (Aldrich) at low rpm onto one of the NAFION® layers. The device precursors were then combined by pressing the two flexible plastic sheets together, with careful alignment of the films from one side to the other to prevent the incorporation of bubbles in the intermediate layer. The intermediate layer dual (Si wire array/Nafion)/PEDOT-PSS membrane was allowed to dry at room temperature and then peeled off of the plastic sheets. The resulting solar fuels generator was able to withstand rolling and unrolling without separation of the layers and/or substantial loss of anode and/or cathode semiconductors.

### Example 2

A device precursor was generated having an anionically conductive material. An SiO₂ mask was patterned on a silicon substrate and silicon wires were grown from a patterned Cu catalyst in a square arrangement with a 7.0 μm pitch. The silicon wires were 90±15 μm long, and ˜1.5-1.7 μm in diameter. The silicon wires were doped p-type. Poly(arylene ether sulfone) functionalized with quaternary ammonium groups (0.050 g, QAPSF) was dissolved in 0.50 mL of DMF, and the solution was spin-coated onto the wire arrays at 1000 rpm for 30 s. The result was then dried at room temperature for >1 h in order to form the cathode layer. This process was performed three times to create a ˜40 μm thick QAPSF layer at the base of the wires. The Si wire array and QAPSF layer were then mechanically removed from the underlying Si substrate using a razor blade.

### Example 3

The hydrogen cross-over rate of the solar fuels generator constructed according to Example 1 was measured. The membrane of the solar fuels generator was sealed with gaskets between two glass flanges in a glass permeation cell that was maintained at room temperature (20° C.) and that contained 2.0 M H₂SO₄(aq) on each side of the membrane. Pt mesh electrodes that had been cleaned with aqua-regia were then positioned within a few mm of each side of the membrane surface. Pure H₂(g) and Ar(g) were bubbled into the cathode and anode compartments, respectively, at 0.3 L min⁻¹, under strong stirring conditions. The cell was left at open circuit for ˜1 h to reach equilibrium conditions. The potential of the anode (Ar saturated side) was then swept at 1 mV s⁻¹ from the rest potential to 800 mV against the cathode (H⁺/H₂), using a Model SI 1286 Schlumberger potentiostat. The hydrogen crossover current density was evaluated at the diffusion-limited hydrogen oxidation current density. The current density was determined by measurement of the area of the membrane that was exposed to the solution. Before measurement of the hydrogen crossover current density for each sample, a similar measurement was made in which pure hydrogen gas was bubbled into each compartment of the permeation cell. The stirring in the anode compartment was adjusted for each sample to achieve the same value for the diffusion-limited hydrogen oxidation current density (3.6 mA cm⁻²) for a hydrogen-saturated solution at 1 atm. This approach ensured that similar mass transport conditions were present for each hydrogen crossover measurement.

The hydrogen crossover rate for the solar fuels generator according to Example 1 was found to be 0.013 mA/cm2 when measured at 20° C. in 2.0 M H₂SO₄ under stirring conditions that resulted in a current density of 3.6 mA cm⁻² in a hydrogen saturated solution at 1 atm. As a result, the hydrogen crossover was less than 0.02 mA/cm² when measured at 20° C. in 2.0 M H₂SO₄ under stirring conditions that resulted in a current density of 3.6 mA/cm² in a hydrogen saturated solution at 1 atm.

### Example 4

The electrical connectivity between wire arrays in a solar fuels generator constructed according to Example 1 was measured by evaporating a film of a metal that formed an ohmic contact to the p-Si on the opposite sides of the membrane. First, to remove the native oxide from the wires, the dual (Si wire array/Nafion)/PEDOT-PSS membrane was immersed for 10 s in 6 M HF(aq), rinsed thoroughly, and dried with N₂ (g). The membrane was then positioned under a shadow mask and ˜200 nm of Au was thermally evaporated onto the p-Si wire array/Nafion surface. The membrane was flipped over and carefully positioned under the shadow mask again to align the metal pads, and another ˜200 nm of Au was evaporated. Ag print was then used to affix two separate coiled Cu wires to the Au-covered spots on each side of the membrane. The membrane was trimmed to a projected area of 0.30 cm², with the entire area covered by Au. An SI Model 1286 Schlumberger potentiostat was used to linearly sweep the voltage between the two sides of the membrane. The current-voltage behavior of the PEDOT-PSS contact was tested as-deposited and also after immersion of the membrane for 6 days in 18 MΩ-cm resistivity H₂O (while the membrane was still wet as well as after the membrane had dried).

After immersion in water for 6 days, the areal resistance increased from 0.30 to 0.40 Ω-cm². After drying under ambient conditions, the resistance returned to ˜0.31 Ω-cm².

### Example 5

The ionic conductivity of the membrane in a solar fuels generator constructed according to Example 1 was measured using a DC galvanodynamic method.²⁹ To ensure full hydration, the solar fuels generator was first immersed in 0.60 M H₂O₂(aq) at 80° C. for ˜2 h, followed by immersion in 0.50 M H₂SO₄(aq) for >48 h. The membrane was sealed with gaskets between two glass flanges in a glass permeation cell. The cell was maintained at room temperature (20° C.) and contained either 2.0 M H₂SO₄(aq) (when testing Nafion) or 2.0 M KOH(aq) (when testing QAPSF) on each side of the membrane. A Pt mesh electrode that had been cleaned with aqua regia was positioned in each compartment of the cell. A Luggin capillary that utilized a Pt wire, in either 2.0 M H₂SO₄(aq) or 2.0 M KOH(aq) (to match the bulk solution), was then introduced into each cell compartment, with the tip of the capillary positioned <2 mm from the membrane. Each capillary tip was attached to the inside of the glass flange with mounting wax, to maintain the position of the tip during loading and unloading of the membrane in the cell. A linear galvanodynamic current sweep from 0 to 400 mA cm⁻² between the two Pt electrodes was performed using a model SI 1286 Schlumberger potentiostat, while the potential was recorded at each Luggin capillary. The current was swept at 1 mA s⁻¹, starting from 0 mA cm⁻² (at the rest potential of the membrane), to produce positive or negative membrane potential differences. Plots of the potential difference versus current displayed ohmic behavior, allowing the cell resistance, R_{cell}, to be extracted from the slope of the plot. The electrolyte resistance, R_{elec}, was determined by measurement of the potential difference as a function of current in the absence of the membrane. The membrane resistance was then calculated using the relationship Rₘₑₘ=R_{cell}−R_{elec}. The ionic conductivity of the membrane, σ, was calculated using σ=RₘₑₘA/L, where A is the area of the membrane exposed to the galvanodynamic sweep and L is the thickness of the membrane.

The cationic conductivity of the membrane measured at 20° C. in 2.0 M H₂SO₄ was found to be 57+/−6 mS/cm. As a result, the membrane has a hydrogen cationic conductivity greater than 50 mS/cm when measured at 20° C., in 2.0 M H₂SO₄.

### Example 6

The optical absorption of a solar fuels generator constructed according to Example 1 was measured. An integrating sphere was used to collect transmission, T, and reflection, R, data for the solar fuels generator. The absorption, A, of the membrane was then determined by A=1−R−T. A tunable, collimated light source was obtained by coupling a supercontinuum laser (Fianium) to a monochromator along with a chopper and lock-in amplifier. Data were collected in 2 nm increments.

The fraction of incident light absorbed by the solar fuels generator was found to be greater than 85% over the range of 450 to 1100 nm and greater than 90% over the range of 500-700 nm. In contrast, the fraction of incident light absorbed by a single NAFION® layer without the presence of wires is less than 5% over the range of 500-700 nm. When the NAFION® layer is combined with a layer of PEDOT: PSS, the absorption is less than 25% over the range of 500-700 nm. Accordingly, the wires absorb more than 65% of the incident light in a range of 500-700 nm even when the incident light is substantially perpendicular to the membrane

Although the cathode layer, the anode layer, and the intermediate layer are each shown above as being constructed of a single layer of material, one or more of these layers can be constructed of multiple layers of material.

Other embodiments, combinations and modifications of this invention will occur readily to those of ordinary skill in the art in view of these teachings. Therefore, this invention is to be limited only by the following claims, which include all such embodiments and modifications when viewed in conjunction with the above specification and accompanying drawings.

1. A solar fuel generator, comprising:
photoanodes extending outward from a first side of a membrane, the photoanodes each including an n-type semiconductor; and
photocathodes extending outward from a second side of the membrane, the photocathodes each including a p-type semiconductor,
the p-type semiconductors being in electrical communication with the n-type semiconductors.

2. The generator of claim 1, wherein the membrane includes multiple layers of material.

3. The generator of claim 2, wherein the n-type semiconductors each extend into an anode layer of the membrane and the p-type semiconductors each extends into a cathode layer of the membrane.

4. The generator of claim 3, wherein the membrane includes an intermediate layer between the anode layer and the cathode layer.

5. The generator of claim 4, wherein the intermediate layer is more electrically conducting than the cathode layer, and
the intermediate layer is more electrically conducting than the anode layer.

6. The generator of claim 4, wherein the n-type semiconductors each physically contacts the intermediate layer, and
the p-type semiconductors each physically contacts the intermediate layer.

7. The generator of claim 4, wherein the n-type semiconductors each extends through the anode layer, and
the p-type semiconductors each extends through the cathode layer.

8. The generator of claim 7, wherein a ratio of a thickness of the anode layer:a thickness of the intermediate layer is greater than 5:1 and a thickness of the cathode layer:a thickness of the intermediate layer is greater than 5:1.

9. The generator of claim 4, wherein the intermediate layer includes one or more ionomers.

10. The generator of claim 9, wherein the one or more ionomers includes poly(3,4-ethylenedioxythiophene): poly(styrene sulfonate).

11. The generator of claim 1, wherein the n-type semiconductors have an average length:width ratio greater than 5:1, and
the p-type semiconductors have an average length:width ratio greater than 5:1.

12. The generator of claim 1, wherein the n-type semiconductors each extend into an anode layer of the membrane,
the anode layer includes a cationically conductive ionomer.

13. The generator of claim 12, wherein the ionomer is a copolymers of a substituted or unsubstituted alkylene and a sulfonic acid.

14. The generator of claim 1, wherein the p-type semiconductors each extends into a cathode layer of the membrane, the cathode layer includes an ionomer.

15. The generator of claim 14, wherein the ionomer is an anionically conductive poly(arylene ether sulfone).

16. The generator of claim 15, wherein the poly(arylene ether sulfone) is represented by the following Formula II: 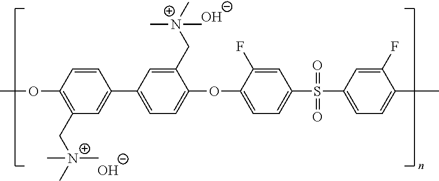
wherein n is greater than 2.

17. The generator of claim 1, wherein a bandgap of the n-type semiconductors is larger than a bandgap of the p-type semiconductors.

18. The generator of claim 1, wherein the p-type semiconductors include p-type silicon, the n-type semiconductors include a metal oxide, and the membrane is ionically conducting while being impermeable to H₂ and O₂, and optically transparent.

19. The generator of claim 1, wherein a portion of a length of each n-type semiconductor is embedded in the membrane while a remaining portion of the length of each n-type semiconductor is located outside of the membrane and an average percentage of the n-type semiconductor length embedded in the membrane is greater than 10%, and
a portion of a length of each p-type semiconductor is embedded in the membrane while a remaining portion of the length of each p-type semiconductor is located outside of the membrane and an average percentage of the p-type semiconductor length embedded in the membrane is greater than 10%.

20. A method of forming a solar fuel generator, comprising:
generating an anode precursor that includes photoanodes extending outward from an anode layer, the photoanodes each including an n-type semiconductor;
generating a cathode precursor that includes photocathodes extending outward from a cathode layer, the photoacathodes each including a p-type semiconductor; and
bonding the anode layer to the cathode layer with an intermediate layer that provides electrical communication between the n-type semiconductors and the p-type semiconductors.
